(19) United States
(12) Patent Application Publication
(10) Pub. No.: US 2011/0260134 A1
(43) Pub. Date: Oct. 27, 2011

(54) Thermally Stable Nanoscale Switching Device

(76) Inventors: Jianhua Yang, Palo Alto, CA (US); Stanley Williams, Portola Valley, CA (US); Julien Borghetti, Mountain View, CA (US); John Paul Strachan, Millbrae, CA (US)

(21) Appl. No.: 13/130,837

(22) PCT Filed: Jul. 30, 2009
(86) PCT No.: PCT/US2009/052250

§ 371 Date: May 24, 2011

Related U.S. Application Data
(63) Continuation-in-part of application No. PCT/US2009/000518, filed on Jan. 26, 2009.

(51) Int. Cl. H01L 45/00

(52) U.S. Cl. 257/4; 257/E45.003

(57) ABSTRACT

A nanoscale switching device provides enhanced thermal stability and endurance to switching cycles. The switching device has an active region disposed between electrodes and containing a switching material capable of carrying a species of dopants and transporting the dopants under an electrical field. At least one of the electrodes is formed of conductive material having a melting point greater than 1800° C.

### BACKGROUND

The continuous trend in the development of electronic devices has been to minimize the sizes of the devices. While the current generation of commercial microelectronics are based on sub-micron design rules, significant research and development efforts are directed towards exploring devices on the nanoscale, with the dimensions of the devices often measured in nanometers or tens of nanometers. Besides the significant reduction of individual device size and much higher packing density compared to microscale devices, nanoscale devices may also provide new functionalities due to physical phenomena on the nanoscale that are not observed on the microscale.

For instance, electronic switching in nanoscale devices using titanium oxide as the switching material has recently been reported. The resistive switching behavior of such a device has been linked to the memristor circuit element theory originally predicted in 1971 by L. O. Chua. The discovery of the memristive behavior in the nanoscale switch has generated significant interests, and there are substantial on-going research efforts to further develop such nanoscale switches and to implement them in various applications. One of the many important potential applications is to use such a switching device as a memory unit to store digital data.

To bring a new device from the laboratory setting to commercial applications, there are often many technical challenges that have to be overcome in order to meet the performance demands of real-world applications. In the case of the nanoscale memristive switching device, one of the major technical challenges is the need to improve the long-term thermal stability of the device. Due to the small size of the switching device, the power needed to operate the device can cause significant localized heating, which can lead to device failure after a number of switching cycles. The limited cycling capability and potential premature failure is undesirable for many applications, such as digital memory, that require the switching device to be able to maintain its operation characteristics after a large number of switching cycles. Thus, improving the thermal Stability and cycling endurance is a pressing issue for the development of the nanoscale switching device.

### BRIEF DESCRIPTION OF THE DRAWINGS

Some embodiments of the invention are described, by way of example, with respect to the following figures:

FIG. 1 is a cross-sectional view of a two-terminal nanoscale switching device formed on a substrate in accordance with an embodiment of the invention;

FIG. 2 is a schematic depiction of the two-terminal nanoscale switching device of FIG. 1 showing its components;

FIG. 3 is a schematic view of a nanoscale three-terminal switching device in accordance with an embodiment of the invention;

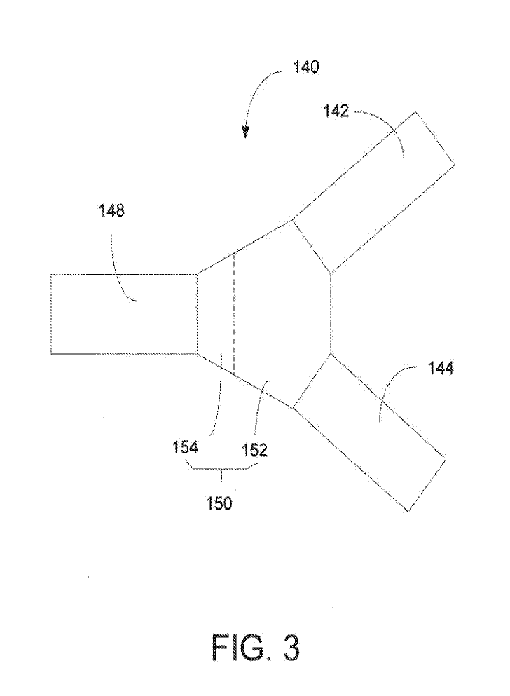

FIG. 4 is top view of a two terminal nanoscale switching device that has a damaged top electrode; and

FIG. 5 is a schematic 3-D view of a crossbar array of two-terminal nanoscale switching devices.

### DETAILED DESCRIPTION

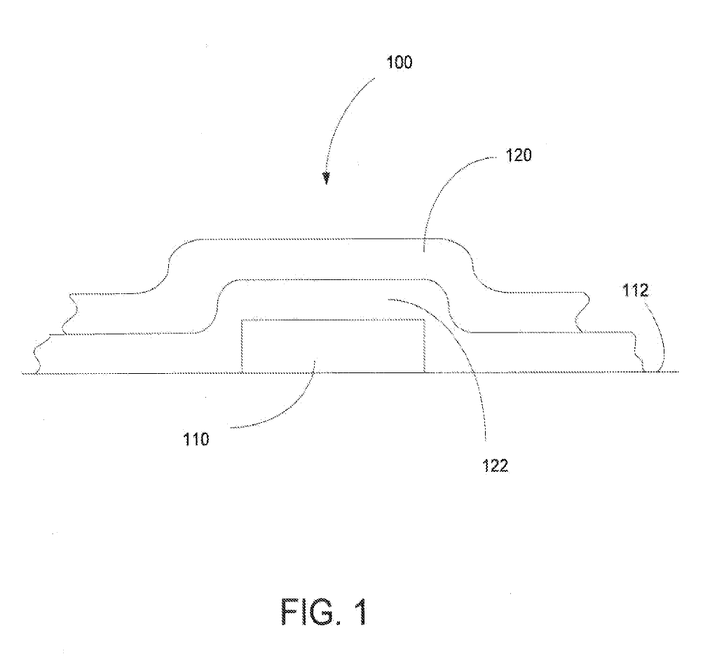

FIG. 1 shows a two-terminal nanoscale switching device 100 in accordance with an embodiment of the invention. The switching device comprises a bottom electrode 110 formed on a substrate 112, a top electrode 120 extending over and intersecting the bottom electrode 110, and an active region 122 disposed between the top and bottom electrodes. As will be described in greater detail below, the active region 122 contains a switching material, the electrical characteristics of which can be controllably modified to allow the device to be switched to ON and OFF states. Each of the top and bottom electrodes 110 and 120 may have a width and a thickness on the nanoscale. For example, the electrodes may have a width in the range of 15 nm to 500 nm, and a width in the range of 5 nm and 500 nm. Likewise, the active region 122 may have a height that is on the nanoscale and typically tens of nanometers. As used hereinafter, the term “nanoscale” means the object has one or more dimensions smaller than one micrometer, and in some embodiments less than 500 nanometers and often less than 100 nanometers. Due to the nanoscale dimensions of the top and bottom electrodes and the active region, the device has a very small volume and relatively limited thermal dissipation capability. As a result, the device is susceptible to heat buildup and thermal damages. As will be described below, the present invention effectively solves this problem and significantly improves the thermal stability and cycling endurance of the device.

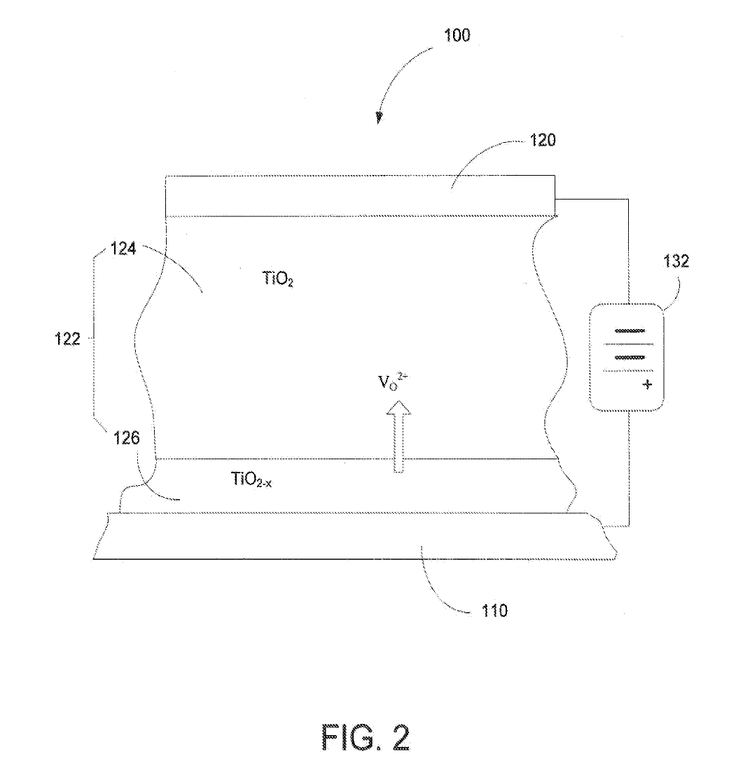

To facilitate a better understanding of the significance of the issue addressed by the invention, the components and operation principles of the switching device 100 are described first, with reference to FIG. 2. As shown in FIG. 2, in one embodiment, the active region 122 between the top electrode 120 and bottom electrode 110 has two sub-regions: a primary active region 124 and a dopant source region 126. The primary active region 124 contains a switching material. The switching material is capable of carrying a species of mobile ionic dopants such that the dopants can be controllably transported into and/or through the switching material to change the electrical properties of either the switching material or the interface of the switching material and an electrode, which in the illustrated embodiment is the top electrode 120. This ability to change the electrical properties as a function of dopant distribution allows the switching device 100 to be placed in different switching states by applying a switching voltage to the electrodes.

Generally, the switching material may be electronically semiconducting or nominally insulating and a weak ionic conductor. Many different materials with their respective suitable dopants can be used as the switching material. Materials that exhibit suitable properties for switching include oxides, sulfides, selenides, nitrides, carbides, phosphides, arsenides, chlorides, and bromides of transition and rare earth metals. Suitable switching materials also include elemental semiconductors such as Si and Ge, and compound semiconductors such as III-V and II-VI compound semiconductors. The III-V semiconductors include, for instance, BN, BP, BSb, AlP, AlSb, GaAs, GaP, GaN, InN, InP, InAs, and InSb, and ternary and quaternary compounds. The II-VI compound semiconductors include, for instance, CdSe, CdS, CdTe, ZnSe, ZnS, ZnO, and ternary compounds. These listings of possible switching materials are not exhaustive and do not restrict the scope of the present invention.

The dopant species used to alter the electrical properties of the switching material depends on the particular type of switching material chosen, and may be cations, anions or vacancies, or impurities as electron donors or acceptors. For instance, In the case of transition metal oxides such as TiO₂, the dopant species may be oxygen vacancies. For GaN, the dopant species may be nitride vacancies or sulfide ions. For compound semiconductors, the dopants may be n-type or p-type impurities.

The dopant source region 126 contains a dopant source material that functions as a source/sink of dopants that can be driven into or out of the switching material in the primary active region 124 to alter the overall resistance of the switching device 100. The dopant source material may be generally the same as the switching material but with a higher dopant concentration. For example, if the switching material is TiO₂, the dopant source material may be TiO₂₋ₓ, where x is a number significantly smaller than 1, such as from 0.01 to 0.1. In this case, the TiO₂₋ₓ material acts as a source/sink of oxygen vacancies (V₍₎²) that can drift into and through the TiO₂ switching material in the primary active region 124.

The nanoscale switching device 100 can be switched between ON and OFF states by controlling the concentration and distribution of dopants in the primary active region 124. When a DC switching voltage from a voltage source 132 is applied across the top and bottom electrodes 120 and 110, an electrical field is created across the active region 122. This electric field, if of sufficient strength and proper polarity, may drive the dopants from the dopant source region 126 into the primary active region 124, and cause the dopants to drift through the switching material in the primary active region 124 towards the top electrode 120, thereby turning the device into an ON state.

If the polarity of the electrical field is reversed, the dopants may drift in an opposite direction across the primary active region 124 and away from the top electrode, thereby turning the device into an OFF state. In this way, the switching is reversible and may be repeated. Due to the relatively large electrical field needed to cause dopant drifting, after the switching voltage is removed, the locations of the dopants remain stable in the switching material. In other words, the switching may be non-volatile.

The state of the switching device may be read by applying a read voltage to the top and bottom electrodes 120 and 110 to sense the resistance across these two electrodes. The read voltage is typically much lower than the threshold voltage required to cause drifting of the ionic dopants between the top and bottom electrodes, so that the read operation does not alter the ON/OFF state of the switching device.

The switching behavior described above may be based on different mechanisms. In one mechanism, the reduction of resistance may be a “bulk” property of the switching material in the primary active region 124. An increase of the dopant level in the switching material causes the resistance across the switching material to fall, and this may account for the decrease of the overall resistance of the device between the top and bottom electrodes.

In another mechanism, the switching behavior may be an “interface” phenomenon. Initially, with a low dopant level in the switching material, the interface of the switching material and the top electrode 120 may behave like a Schottky barrier, with a high electronic barrier that is difficult for electrons to tunnel through. As a result, the device has a relatively high resistance. When dopants are injected into the switching material by applying a switching voltage, the dopants drift towards the top electrodes 120. The increased concentration of dopants at the electrode interface changes its electrical property from one like a Schottky harrier to one like an Ohmic contact, with a significantly reduced electronic barrier height or width. As a result, electrons can tunnel through the interface much more easily, and this may account for the significantly reduced overall resistance of the switching device. It is also possible that the resistance change is the result of a combination of both the bulk and interface mechanisms. Even though there may be different mechanisms for explaining the switching behavior, it should be noted that the present invention does not rely on or depend on any particular mechanism for validation, and the scope of the invention is not restricted by which switching mechanism is actually at work.

In the foregoing description with reference to FIGS. 1 and 2, a nanoscale switching device with two electrodes or terminals has been described. A nanoscale switching device may, however, have more than two terminals. For instance, FIG, 3 shows an embodiment of a switching device 140 with three terminals. The switching device 140 has an active region 150 that is divided into a primary active region 152 containing a switching material, and a dopant source region 154 that contains a dopant source material. The switching device 140 also has three electrodes. The first electrode 142 and second electrode 144 are disposed to be in electrical contact with the primary active region 152, while the third electrode 148 is disposed in electrical contact with the dopant source region 154. The third electrode 148 may be used for switching of the device, while the first and second electrodes 142, 144 may be used for sensing the state of the device. Initially, the switching material in the primary active region 152 may have a low dopant concentration, and as a result the resistance of the device as measured between the first anti second electrodes 142, 144 is high. This may be the OFF state of the device. When a switching voltage of sufficient magnitude and proper polarity is applied to the third electrode 148 with respect to the first and second electrodes, the electrical field causes the ionic dopants to drift from the dopant source material into and across the switching material in the primary active region 152 towards the first and second electrodes. The injection and redistribution of the ionic dopants in the primary active region 152 may significantly reduce the resistance of the device measured between the first and second electrodes. When the resistance is reduced to a predefined value, the device is said to have been switched to the ON state.

As mentioned above, due to its small volume and limited heat dissipation capability, the nanoscale switching device may be subject to substantial heating and temperature rise during operation. For instance, in a typical switching operation, the voltage needed to switch the device ON may be as high as 20 volts, and the current may be up to 200 microamps. This amount of power can heat the nanoscale switching device to a fairly high temperature and cause severe thermal stress to the device. Nanoscale switching devices prior to this invention had thermal stability issues and could break down after going through multiple switching cycles.

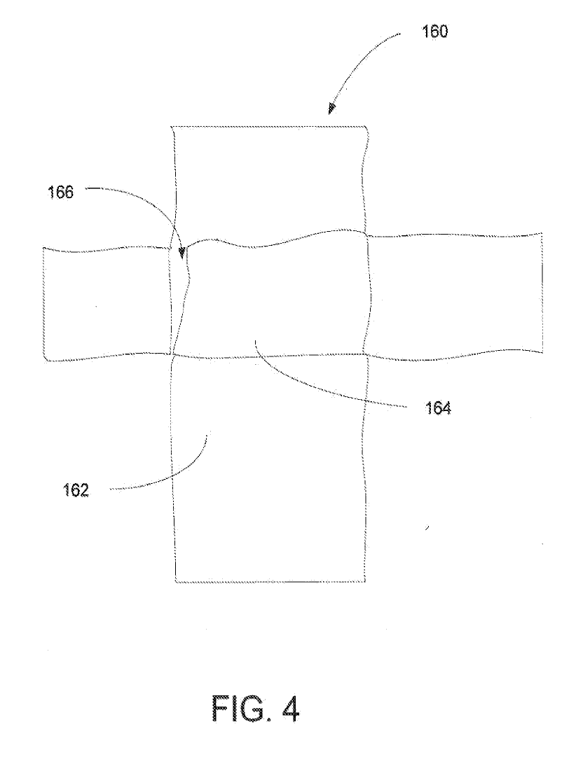

In connection with this invention, it has been discovered by the inventors that a major cause of the device failure is the heat-induced diffusion or electro-migration of the electrode material. FIG. 4 depicts such a pre-invention nanoscale two-terminal switching device that is broken due to thermal damages caused by multiple switching cycles. The electrodes of the device 160 are made of platinum. As shown in FIG. 4, the top electrode 164 of the switching device 160 is damaged with a portion missing, leaving a gap 166 that breaks the electrical conductivity of the top electrode. This indicates strong diffusion of the platinum electrode material into the switching material. It has also been observed that the grain size of the platinum electrode material has increased significantly after the switching cycles, which is another indication of substantial heating and thermal diffusion. The breaking of the electrode 164 caused by diffusion of the electrode material into the switching material creates an open circuit and thus leaves the switching device in a permanent OFF state. On the other hand, even if the electrode is not broken, the diffusion of the electrode material into the switching material could make the switching material so conductive that the device is left in a permanent ON state.

In accordance with an embodiment of the invention, this thermal stability issue is effectively addressed by using conductive materials that are highly thermodynamically stable to form one or more electrodes of the device. Specifically, at least one of the electrodes of the nanoscale switching device is formed of a conductive material that has a sufficiently high melting point so that the diffusion of the electrode material due to heating or electron momentum transfer is substantially reduced. The melting point of the conductive material is in some embodiments at least 1800° C., which is higher than the melting point of platinum and in other embodiments greater than 2200° C. Suitable materials for forming the electrodes include, for example, metals such as tungsten, tantalum, niobium, and molybdenum, and conductive ceramic materials such as titanium nitride, ruthenium oxide, titanium carbide, and tungsten carbide.

Whether all electrodes of the switching device need to be formed of the high-melting-point conductive material depends on the thermal dissipation characteristics of the device. For instance, in the two-terminal switching device shown in FIG. 1, the bottom electrode 110 is in proximity to the substrate 112 and could be able to dissipate heat faster than the top electrode 120 could. As a result, the top electrode 120 is likely to be subject to greater heating and thermal variations. Accordingly, in this embodiment, at least the top electrode 120 should be formed of a high-melting-point conductive material. Nevertheless, it may be desirable to form both top and bottom electrodes with the high-melting-point conductive material to provide enhanced thermal stability of the switching device.

In addition to high melting point metallic or conductive ceramic materials, some materials with relatively low melting points, such as indium tin oxide, can also he practical choices for the electrode materials. The reason is that a small amount of diffused indium or tin forms semiconducting oxide in the switching materials and such semiconducting oxide will not cause serious failure to the switching device, such as putting the device in a permanent ON state.

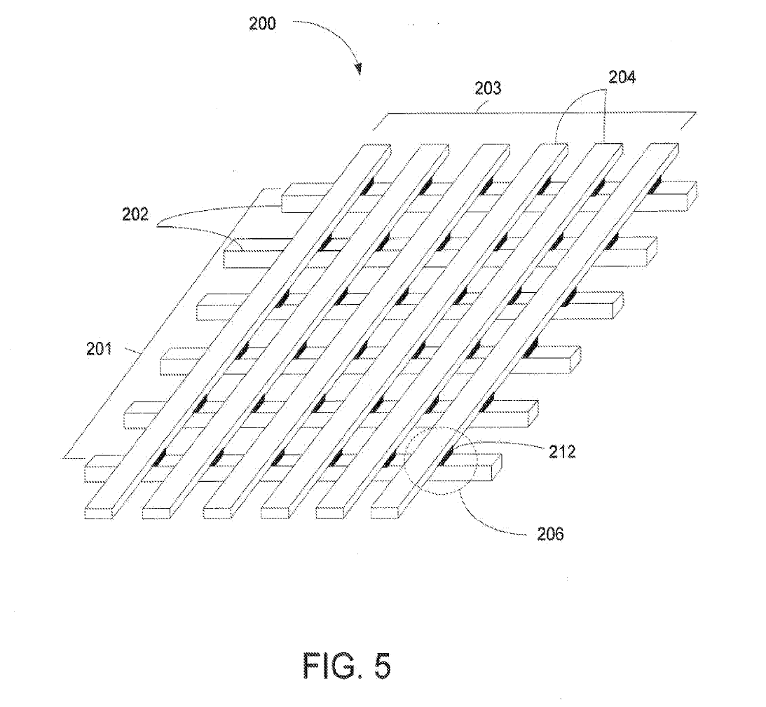

The thermally stable nanoscale switching device may be formed into an array for various applications. FIG. 5 shows an example of a two-dimensional array of such switching devices. The array has a first group 201 of generally parallel nanowires 202 running in a first direction, and a second group 203 of generally parallel nanowires 204 running in a second direction at an angle, such as 90 degrees, from the first direction. The two layers of nanowires 202 and 204 form a two-dimensional lattice which is commonly referred to as a crossbar structure, with each nanowire 202 in the first layer intersecting a plurality of the nanowires 204 of the second layer. A two-terminal switching device 206 may be formed at each intersection of the nanowires 202 and 204. The switching device 206 has a nanowire of the second group 203 as its top electrode and a nanowire of the first group 201 as the bottom electrode, and an active region 212 containing a switching material between the two nanowires. In accordance with an embodiment of the invention, at least the nanowires 204 of the second group 203 are formed of a high-melting-point conductive material having a melting point greater than 1800° C., and in some other embodiments 2200° C., to provide improved thermal stability of the switching devices in the crossbar array.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A nanoscale switching device comprising:
a first electrode of a nanoscale width;
a second electrode of a nanoscale width;
an active region disposed between and in electrical contact with the first and second electrodes, the active region containing a switching material capable or carrying a species of dopants and transporting the dopants under an electrical field;
wherein at least one of the first and second electrodes is formed of a conductive material having a melting point greater than 1800° C.

2. A nanoscale switching device as in claim 1, wherein the conductive material has a melting point greater than 2200° C.

3. A nanoscale switching device as in claim 1, wherein the conductive material is a metal.

4. A nanoscale switching device as in claim 3, wherein the conductive material is tungsten.

5. A nanoscale switching device as in claim 1, wherein the conductive material is a conductive ceramic material.

6. A nanoscale switching device as in claim 5, wherein the conductive material is titanium nitride.

7. A nanoscale switching device as in claim 1, wherein the switching material is a metal oxide.

8. A nanoscale switching device as in claim 1, wherein the switching material is a semiconductor.

9. A nanoscale crossbar array comprising:
a first group of conductive nanowires running in a first direction;
a second group of conductive nanowires running in a second direction and intersecting the first group of nanowires;
a plurality of switching devices formed at intersections of the first and second groups of nanowires, each switching device having a first electrode formed by a first nanowire of the first group and a second electrode formed by a second nanowire of the second group, and an active region disposed at the intersection between the first and second nanowires and comprising a switching material capable of carrying a species of dopants and transporting the dopants under an electrical field,
wherein at least the nanowires of the first group are formed of a conductive material having a melting point greater than 1800° C.

10. A nanoscale crossbar array as in claim 9, wherein the conductive material has a melting point greater than 2200° C.

11. A nanoscale crossbar array as in claim 9, where in the conductive material is a metal.

12. A nanoscale crossbar array as in claim 11, wherein the conductive material is tungsten.

13. A nanoscale crossbar array as in claim 9, wherein the conductive material is a conductive ceramic material.

14. A nanoscale crossbar array as in claim 9, wherein the switching material is a metal oxide.

15. A nanoscale crossbar array as in claim 9, wherein the switching material is a semiconductor.
